(19) United States
(12) Patent Application Publication
(10) Pub. No.: US 2011/0241114 A1
(43) Pub. Date: Oct. 6, 2011

(54) HIGH VOLTAGE MOS TRANSISTOR

(75) Inventors: RU-YI SU, Yunlin County (TW); Fu-Chih Yang, Kaochsiung County (TW); Chun Lin Tsai, Hsinchu (TW); Ker-Hsiao Huo, Taichung City (TW); Chia-Chin Shen, Hsinchu City (TW); Eric Huang, Hsinch County (TW); Chih-Chang Cheng, Hsinchu City (TW); Ruey-Hsin Liu, Hsinchu (TW); Hsiao-Chin Tuan, Judong County (TW)

(73) Assignee: TAIWAN SEMICONDUCTOR MANUFACTURING COMPANY, LTD., Hsin-Chu (TW)

(21) Appl. No.: 12/753,486

(22) Filed: Apr. 2, 2010

(51) Int. Cl. H01L 29/78; H01L 21/336

(52) U.S. Cl. 257/343; 438/286; 257/E21.417; 257/E29.261

(57) ABSTRACT

A high voltage metal-oxide-semiconductor laterally diffused device (HV LDMOS) and a method of making it are provided in this disclosure. The device includes a semiconductor substrate, a gate structure formed on the substrate, a source and a drain formed in the substrate on either side of the gate structure, a first doped well formed in the substrate, and a second doped well formed in the first well. One portion of the second well surrounds the source and the other portion of the second well extends laterally from the first portion in the first well.

### BACKGROUND

The present disclosure relates generally to semiconductor technology, and more particularly, to high voltage semiconductor devices and methods of making the same.

Technological advances in semiconductor integrated circuit (IC) materials, design, processing, and manufacturing have enabled ever-shrinking IC devices, where each generation has smaller and more complex circuits than the previous generation.

As semiconductor circuits composed of devices such as metal-oxide-semiconductor field effect transistors (MOSFETs) are adapted for high voltage applications, such as high voltage lateral diffusion metal-oxide-semiconductor devices (HV LDMOSs), problems arise with respect to decreasing voltage performance as the scaling continues with advanced technologies. To prevent punch-through between source and drain, or to reduce resistance of source and drain, standard MOS fabrication process flows may be accompanied by multiple implantations of high concentrations. Unfortunately, voltage breakdown often occurs and device reliability degrades.

Performance of a HV MOS transistor is often limited by its breakdown voltage (BV) threshold. A number of techniques developed to improve the breakdown voltage have typically increased the device's on-state resistance Rₒₙ, which depends on the breakdown voltage BV of a HV MOS device in a relationship described as:

Rₒₙ=constant*BV^{2.5}(Ωcm²)

A higher breakdown voltage BV induces a much higher (to the power of 2.5) resistance Rₒₙ, thus a much higher power consumption (P=I²Rₒₙ). For example, a 33% increase in breakdown voltage BV doubles the power loss.

Therefore, there is a need for a HV LDMOS device, which has a high breakdown voltage threshold, yet maintains a low power consumption, and a method of making the same.

### SUMMARY

One embodiment of the present invention is a high voltage MOS semiconductor device. The high voltage semiconductor device includes a lightly doped semiconductor substrate having a first type of conductivity; an insulating structure formed on top of the semiconductor substrate; a gate structure formed partly on the oxide structure and partly on the substrate; a drain and a source formed on either side of the gate structure. A second well is formed in the first well and has the first type of conductivity. The drain having the second type of conductivity is formed in the first well, and the source is formed in the second well. The second well includes a portion surrounding the source and another portion extending laterally from the first portion toward the drain. In some embodiments, the source also includes one portion having the first type of conductivity and another portion having the second type of conductivity.

Another embodiment of the present invention is a method for fabricating a high voltage MOS semiconductor device. The method includes: providing a lightly doped semiconductor substrate having a first type of conductivity; forming a doped first well in the substrate, the first well having a second type of conductivity different from the first type of conductivity; forming a first doped portion of a second well in the first well, the first portion occupying a region starting from the top surface of the first well and extending down into the first well; forming a second doped portion of the second well in the first well, the second portion extending laterally from the first portion toward the drain, and both first and second portions having the first type of conductivity; forming an insulating layer on the substrate; and forming a gate structure on the substrate. The gate structure has a first part overlying the insulating layer, a second part overlying the first well and a third part overlying the first portion of the second well. The method further includes forming a source in the second well and a drain in the first well, the source and drain residing on either side of the gate structure.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A and FIG. 1B show cross-sectional views of two types of HV LDMOS transistor devices, according to one or more embodiments of the present disclosure.

FIG. 2 shows a cross-sectional view of a HV LDMOS transistor according to alternative embodiments of the present disclosure.

FIG. 3 is a flow chart of a method for fabricating a HV LDMOS device according to various aspects of the present disclosure.

FIG. 4 demonstrates a high breakdown voltage of an exemplary HV LDMOS device with a P-body extension, according to some embodiments of the present disclosure.

### DETAILED DESCRIPTION

The present disclosure relates to semiconductor HV LDMOS transistors with high breakdown voltage thresholds and a method for fabricating such devices. It is understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

Spatially relative terms, such as “beneath,” “below,” “lower,” “above,” “upper”, “over” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may likewise be interpreted accordingly.

Hereinafter, embodiments of the present invention will be explained in detail with reference to the accompanying drawings.

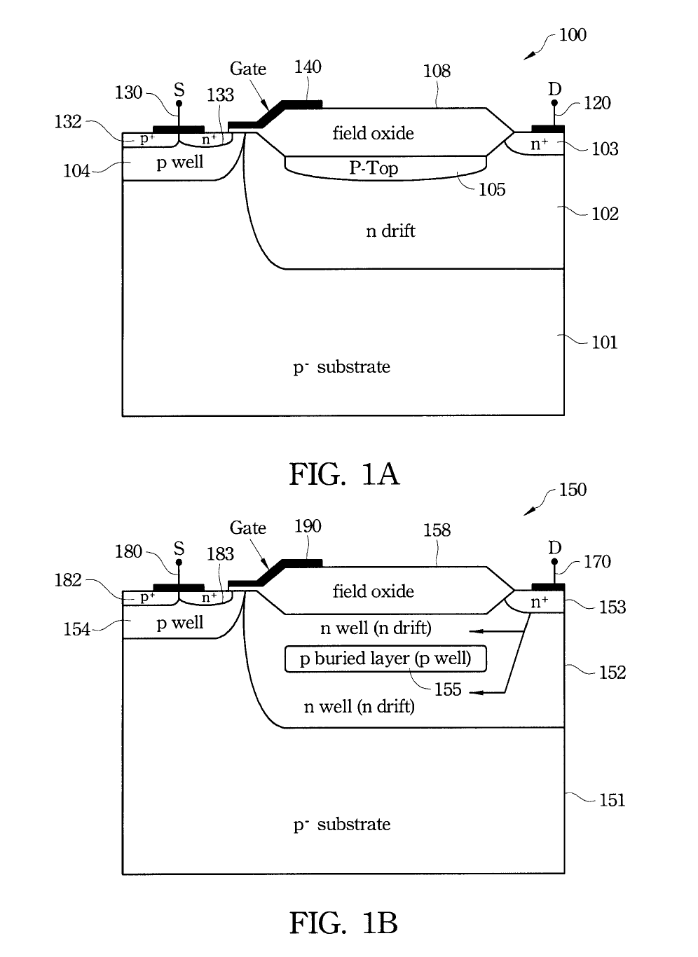

FIG. 1A shows a cross-sectional view of a HV LDMOS transistor according to some embodiments of the present disclosure. In FIG. 1A, an n-type HV MOS device 100 is fabricated in a p-substrate 101. A deep n-well (n-drift) 102 is formed in the substrate 101. A field oxide 108 is formed over the n-well 102 and a gate 140 is partly overlying the field oxide 108. A source and a drain are formed on opposite sides of the gate 140. The source includes a pair of oppositely doped regions p+ (132) and n+ (133) contained in a p-well 104. Source terminal 130 is electrically connected to the source regions 132 and 133. On one side of gate 140 and at the edge of field oxide 108, n+ doped drain region 120 is formed in n-well 102 and electrically connected to a drain terminal 120. A p-top region 105 is formed between field oxide 108 and the deep implanted n-drift region 102. The p-top region 105 is a floating layer and is not connected to the source or the drain region.

FIG. 1B is a cross-sectional view of another HV LDMOS device 150, according to another embodiment of the present disclosure. Unlike device 100 in FIG. 1A, device 150 has the p-top layer replaced by a buried p-well 155. In FIG. 1B, an n-type HV LDMOS device 150 is fabricated in a p-substrate 151. A deep n-well (n-drift) 152 is formed in the substrate 151. A field oxide 158 is formed on the n-well 152 and a gate 190 is partly overlying the field oxide 158. A source and a drain are formed on either side of the gate 190. The source includes a p-type region p+ (182) and a n-type region N+ (183), both contained in a p-well 154. Source terminal 180 is electrically connected to source regions 182 and 183. On the opposite side of gate 190 and at the edge of field oxide 158, n+ doped drain region 170 is formed in n-well 152 and is electrically connected to a drain terminal 170. A deep implanted region p-well 155 is formed in the middle of the deep implanted n-drift region 152 and is also under but not connected to field oxide 158. The buried p-well region 155 is a floating layer and is not connected to the source or the drain region.

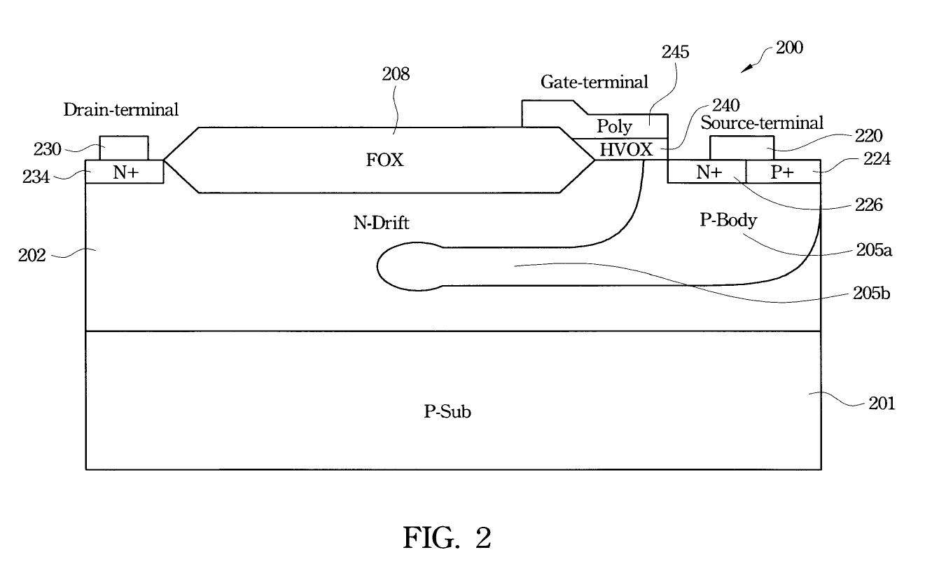

FIG. 2 shows a cross-sectional view of a HV LDMOS transistor 200 according to one or more alternative embodiments of the present disclosure. In FIG. 2, a lightly doped substrate 201 having a first type of conductivity is provided. In the present embodiment, the HV LDMOS transistor 200 is an n-type HV LDMOS, and thus, the substrate 201 includes a p-type silicon substrate (p-substrate). The substrate may include a semiconductor wafer, such as a silicon wafer. Alternatively, the substrate may include other elementary semiconductors, such as germanium. The substrate may also include a compound semiconductor, such as silicon carbide, gallium arsenic, indium arsenide, and indium phosphide. The substrate may include an alloy semiconductor, such as silicon germanium, silicon germanium carbide, gallium arsenic phosphide, and gallium indium phosphide. In one embodiment, the substrate includes an epitaxial layer (epi layer) overlaying a bulk semiconductor. Furthermore, the substrate may include a semiconductor-on-insulator (SOI) structure. For example, the substrate may include a buried oxide (BOX) layer formed by a process such as separation by implanted oxygen (SIMOX). In various embodiments, the substrate may include a buried layer such as an n-type buried layer (NBL), a p-type buried layer (PBL), and/or a buried dielectric layer including a buried oxide (BOX) layer.

As shown in FIG. 2, a first well 202 is formed in the substrate, the first well having a second type of conductivity. For example, the first type of conductivity is a p-type conductivity and the second type of conductivity is an n-type conductivity. In the present embodiment, the first well 202 is an N-Drift (n-well) formed in the p-substrate 201.

A second well 205 is formed in the substrate, the second well having the first type of conductivity. The second 205 is a P-body. The second well may have different portions, each portion having a different location and depth in the first well from the other portion. The two portions may be formed in separate doping processes. For example, shown in FIG. 2, the second well P-Body has a portion 205a, which surrounds source regions 224 and 226, and another portion 205b, which extends out from the portion 205a in a direction towards the drain. In one embodiment of the present disclosure, portion 205b may be deeply buried in the middle of N-Drift 202. In an alternative embodiment of the present disclosure, portion 205b may be placed near the top surface of the N-Drift 202. Portion 205a and portion 205b of the P-Body are attached. The N-Drift and the P-Body may be a portion of the substrate, and may be formed by various ion implantation process. Alternatively, the N-Drift and the P-well may be portions of an epitaxy layer, such as a silicon epitaxy layer formed by epitaxy processing. The N-Drift may have an n-type dopant such as phosphorus, and the P-Body may have a p-type dopant such as boron. In one embodiment, the N-Drift and P-Body may be formed by a plurality of processing steps, whether now known or to be developed, such as growing a sacrificial oxide on the substrate, opening a pattern for the location(s) of the P-Body regions or N-Drift region, and implanting the impurities.

A field insulating layer 208 is formed on the substrate. A gate structure is formed on the substrate, the gate structure having a first portion overlying the first well N-Drift 202 and a second portion overlying the second well P-Body. In the present embodiment, the gate structure includes a gate dielectric 240 formed on the substrate, and a gate electrode 245 formed on the gate dielectric 240. The gate dielectric 240 may include a silicon dioxide (referred to as silicon oxide) layer suitable for high voltage applications. Alternatively, the gate dielectric 240 may optionally include a high-k dielectric material, silicon oxynitride, other suitable materials, or combinations thereof. The high-k material may be selected from metal oxides, metal nitrides, metal silicates, transition metal-oxides, transition metal-nitrides, transition metal-silicates, oxynitrides of metals, metal aluminates, zirconium silicate, zirconium aluminate, HfO₂, or combinations thereof. The gate dielectric 240 may have a multilayer structure, such as one layer of silicon oxide and another layer of high-k material. The gate dielectric 240 may be formed using chemical vapor deposition (CVD), physical vapor deposition (PVD), atomic layer deposition (ALD), thermal oxide, other suitable processes, or combinations thereof.

The gate electrode 245 may be configured to be coupled to metal interconnects and may be disposed overlying the gate dielectric 240. The gate electrode 245 may include a doped or non-doped polycrystalline silicon (or polysilicon). Alternatively, the gate electrode layer 245 may include a metal, such as Al, Cu, W, Ti, Ta, TiN, TaN, NiSi, CoSi, other suitable conductive materials, or combinations thereof. The gate electrode layer 245 may be formed by CVD, PVD, ALD, plating, and other proper processes. The gate electrode layer may have a multilayer structure and may be formed in a multiple-step process.

A drain 234 may be formed in the first well N-drift 202 and connected to drain terminal 230 from above. A source is formed in the top surface of the upper portion of the second well P-Body. In the present embodiment, the source has two oppositely doped regions 224 and 226, both formed in the top surface of the upper portion 205a of the second well P-Body and both connected to source terminal 220 from above. The source's first region 226 and drain 234 may have the second type of conductivity, and the source's second region 224 may have the first type of conductivity. For example in FIG. 2, the source's first region 226 and drain 234 include n-type dopants, such as P or As, and the source's second region 224 includes p-type dopants, such as B. Alternatively, the source could have one type of conductivity, connecting to source terminal 220. The source and drain may be positioned on both sides of the gate terminal 245 and dielectric 240. The source and drain may be formed by a method, such as ion implantation or diffusion. A rapid thermal annealing (RTA) process may be used to activate the implanted dopants.

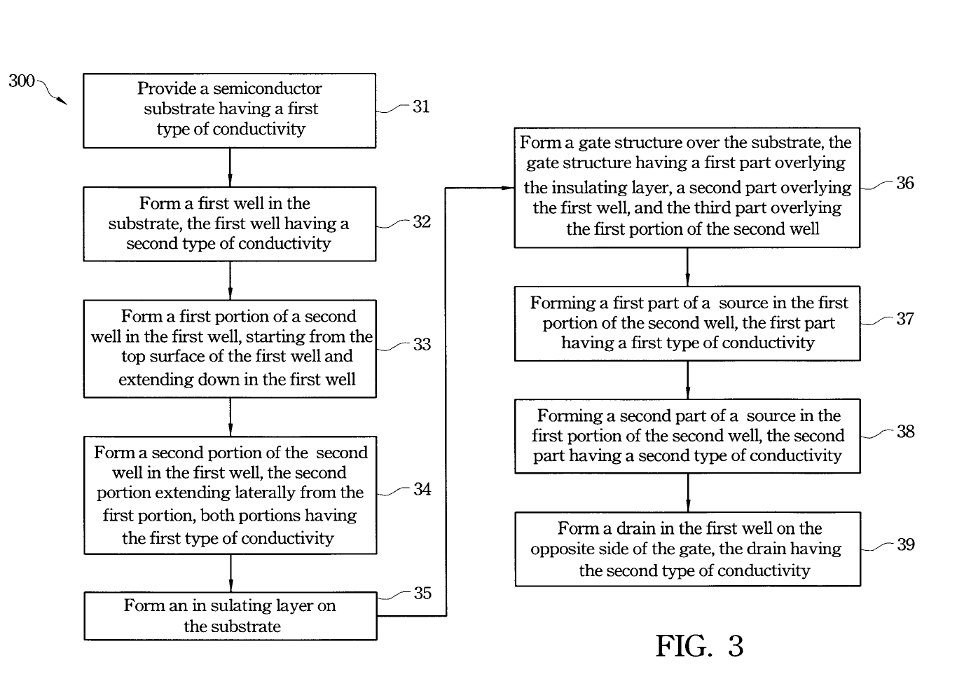

FIG. 3 is a flowchart of a method 300 for fabricating a high voltage laterally diffused MOS semiconductor device, according to various aspects of the present disclosure. It should be noted that the method 300 may be implemented in a complementary metal oxide semiconductor (CMOS) technology process flow. Accordingly, it is understood that additional processes may be provided before, during, and after the method 300, and some processes may only be briefly described herein. The method 300 begins with block 31 in which a semiconductor substrate is provided. The substrate has a first type of conductivity. For example, the substrate may be p-type as the substrate 201 in FIG. 2. The method 300 continues at block 32 in which a first well is formed in the substrate, the first well having a second type of conductivity, which is different from the first type of conductivity. For example, the first well may be an n-well, such as the n-well (N-Drift) 202 formed in the p-substrate 201 in FIG. 2. The method 300 continues with block 33 in which a first portion of a second well is formed in the first well. The first portion of the second well starts from the top surface of the first well and extends down in the first well. The method 300 continues with block 34 in which a second portion of the second well is formed in the first well, this second portion extends laterally from the first portion beyond the top surface of the first portion of the second well. The first and second portions of the second well have the first type of conductivity. For example, the second well is p-type doped, such as the second well P-Body illustrated in FIG. 2, which includes the first portion 205a and second portion 205b (the second portion 205b extends out laterally from the first portion 205a).

The method 300 continues with block 35 in which an insulating layer is formed on the substrate. The insulating layer may include a dielectric, such as silicon oxide, nitride, or other suitable insulating materials. In high voltage MOS devices, this insulating layer may be a thick field oxide, such as the FOX 208 illustrated in FIG. 2.

In the next block 36, in the method 300, a gate structure is built over the substrate. The gate structure has a lower dielectric layer and an upper electrode layer. The gate structure overlies three areas: a first part of the gate structure overlies the edge of the insulating layer, a second part of the gate structure overlies the top surface of the first well, and the third part of the gate structure overlies the first portion of the second well. The precise overlay of the gate structure to the three areas are achieved by a process including photolithography patterning and etching. One exemplary method for patterning the gate dielectric and electrode layers over the three areas is described below. A layer of photoresist is formed on the polysislicon electrode layer by a suitable process, such as spin-on coating, and then patterned to form a patterned photoresist feature by a proper lithography patterning method. The pattern of the photoresist can then be transferred by a dry etching process to the underlying polysilicon layer and the gate dielectric layer to form gate electrodes and gate dielectric, in a plurality of processing steps and various proper sequences. The precise overlay of the gate structure to the field oxide, the first well, and the second well is controlled by the lithographic alignment procedure. The photoresist layer may be stripped thereafter. In another embodiment, only the gate electrode layer is pattered. In another embodiment, a hard mask layer may be used and formed on the polysilicon layer. The patterned photoresist layer is formed on the hard mask layer. The pattern of the photoresist layer is transferred to the hard mask layer and then transferred to the polysilicon layer to form the gate electrode. The hard mask layer may include silicon nitride, silicon oxynitride, silicon carbide, and/or other suitable dielectric materials, and may be formed using a method such as CVD or PVD.

The method 300 continues with block 37, in which a first part of a source region is formed, the first part source region may have the first type of conductivity. In the next block of the method 300, a second part of the source is formed next to the first part, the second part source having the second type of conductivity. For example, the first part source is p-type, and the second part source is n-type. In an alternative embodiment, the first part and the second part of the source may have the same conductivity, thus the block 37 and 38 are combined into one step.

The method 300 continues with block 39, in which a drain region is formed in the first well on the opposite side of the gate structure than the source region. The drain region may be doped with the second type of conductivity. For example, the drain is n-type.

It is understood that the semiconductor device may undergo further processing as is known in the art. For example, making the semiconductor device may further include forming various contacts and metal features on the substrate. Also, a plurality of patterned dielectric layers and conductive layers may be formed on the substrate to form multilayer interconnects configured to couple the various p-type and n-type doped regions, such as the source, drain region, contact region, and gate electrode.

Also, a plurality of patterned dielectric layers and conductive layers are formed on the substrate to form multilayer interconnects configured to couple the various p-type and n-type doped regions, such as the source, drain region, contact region, and gate electrode. In one embodiment, an interlayer dielectric (ILD) and a multilayer interconnect (MLI) structure are formed in a configuration such that the ILD separates and isolates each metal layer from other metal layers. In furtherance of the example, the MLI structure includes contacts, vias and metal lines formed on the substrate. In one example, the MLI structure may include conductive materials, such as aluminum, aluminum/silicon/copper alloy, titanium, titanium nitride, tungsten, polysilicon, metal silicide, or combinations thereof, being referred to as aluminum interconnects. Aluminum interconnects may be formed by a process including physical vapor deposition (or sputtering), chemical vapor deposition (CVD), or combinations thereof. Other manufacturing techniques to form the aluminum interconnect may include photolithography processing and etching to pattern the conductive materials for vertical connection (via and contact) and horizontal connection (conductive line). Alternatively, a copper multilayer interconnect may be used to form the metal patterns. The copper interconnect structure may include copper, copper alloy, titanium, titanium nitride, tantalum, tantalum nitride, tungsten, polysilicon, metal silicide, or combinations thereof. The copper interconnect may be formed by a technique including CVD, sputtering, plating, or other suitable processes.

The ILD material includes silicon oxide. Alternatively or additionally, the ILD includes a material having a low dielectric constant, such as a dielectric constant less than about 3.5. In one embodiment, the dielectric layer includes silicon dioxide, silicon nitride, silicon oxynitride, polyimide, spin-on glass (SOG), fluoride-doped silicate glass (FSG), carbon doped silicon oxide, Black Diamond® (Applied Materials of Santa Clara, California), Xerogel, Aerogel, amorphous fluorinated carbon, Parylene, BCB (bis-benzocyclobutenes), SiLK (Dow Chemical, Midland, Michigan), polyimide, and/or other suitable materials. The dielectric layer may be formed by a technique including spin-on, CVD, or other suitable processes.

MLI and ILD structure may be formed in an integrated process such as a damascene process. In a damascene process, a metal such as copper is used as conductive material for interconnection. Another metal or metal alloy may be additionally or alternatively used for various conductive features. Accordingly, silicon oxide, fluorinated silica glass, or low dielectric constant (k) materials can be used for ILD. During the damascene process, a trench is formed in a dielectric layer, and copper is filled in the trench. Chemical mechanical polishing (CMP) technique is implemented afterward to etch back and planarize the substrate surface.

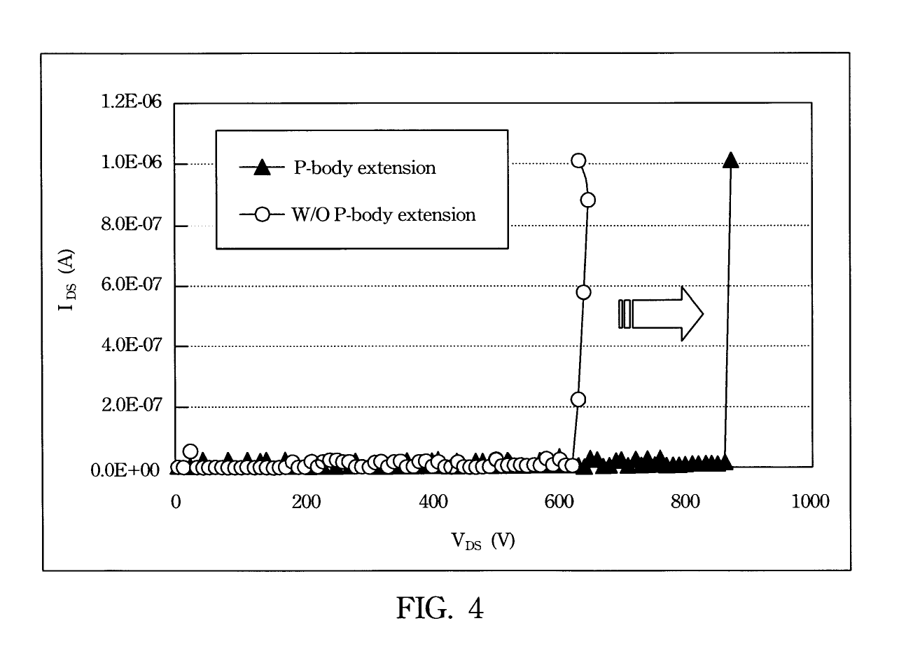

Among various embodiments, the present structure provides an enhanced performing high voltage device, configured as a lateral diffused MOS (HV LDMOS) formed in a dual-well structure (an extended p-type well inside an n-type well) within the substrate. FIG. 4 exhibits a high breakdown voltage of an exemplary HV LDMOS device, according to some embodiments of the present disclosure. A HV LDMOS device having the disclosed P-body extension as described in FIG. 2 demonstrated its source-drain current breaking down at 880V, a 32% improvement over another HV MOS device without the extended P-Body. In addition, the P-Body extension connects to the source directly, forcing the current flow near the N-drift surface, thus reducing the on-stage resistance Rₒₙ during the device operation. Therefore, the disclosed device also saves the overall device power consumption. It is understood that different embodiments may have different advantages, and that no particular advantage is necessarily required of any embodiment.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A high voltage semiconductor transistor, comprising:
a lightly doped semiconductor substrate having a first type of conductivity;
a first well region having a second type of conductivity and formed in the substrate;
an insulating structure formed over the semiconductor substrate;
a gate structure formed over the substrate and near the insulating structure;
a drain region and a source region formed on respective opposite sides of the gate structure;
a second well region formed in the first well region and having the first type of conductivity; and
the source region is formed in the second well region, wherein the second well region comprises a first portion and a second portion, the first portion surrounding the source region and the second portion extending laterally under the gate structure.

2. The high voltage semiconductor transistor of claim 1, the source region comprising a first region having the first type of conductivity and a second region having the second type of conductivity.

3. The high voltage semiconductor transistor of claim 1, wherein the second portion of the second well extends laterally under the gate structure toward the drain.

4. The high voltage semiconductor transistor of claim 1, wherein the gate structure comprises a gate electrode and a gate dielectric.

5. The high voltage semiconductor transistor of claim 4, wherein the gate electrode comprises polysilicon.

6. The high voltage semiconductor transistor of claim 4, wherein the gate electrode comprises metal.

7. The high voltage semiconductor transistor of claim 6, wherein the metal comprises Al, Cu, W, Ti, Ta, TiN, TaN, NiSi, CoSi, or combination thereof.

8. The high voltage semiconductor transistor of claim 4, wherein the gate dielectric comprises silicon oxide, a high-K dielectric material, or silicon oxynitride.

9. The high voltage semiconductor transistor of claim 8, wherein the high-k material comprises metal oxides, metal nitrides, metal silicates, transition metal-oxides, transition metal-nitrides, transition metal-silicates, oxynitrides of metals, metal aluminates, zirconium silicate, zirconium aluminate, HfO₂, or combinations thereof.

10. The high voltage semiconductor transistor of claim 1, the gate structure is formed partly on the insulating structure and partly on the substrate.

11. The high voltage semiconductor transistor of claim 1, wherein the drain region is formed in the first well region and has the second type of conductivity, and the source region is formed in the second well region.

12. A high voltage semiconductor transistor, comprising:
a lightly doped semiconductor substrate having a first type of conductivity;
a first well region having a second type of conductivity and formed in the substrate;
an insulating structure formed over the semiconductor substrate;
a gate structure formed over the substrate and near the insulating structure;
a drain region and a source region formed on respective opposite sides of the gate structure; and
a second well region formed in the first well region and having the first type of conductivity and the source region is formed in the second well region,
wherein the second well region comprises a first portion overlying a second portion, the first portion extending up to connect the source region and the second portion extending laterally beyond the first portion.

13. The high voltage semiconductor transistor of claim 12, the source region comprising a first region having the first type of conductivity and a second region having the second type of conductivity.

14. The high voltage semiconductor transistor of claim 12, wherein the second portion extends laterally beyond the first portion along the top surface of the first well region.

15. The high voltage semiconductor transistor of claim 12, the gate structure is formed partly on the insulating structure and partly on the substrate.

16. The high voltage semiconductor transistor of claim 12, wherein the drain region is formed in the first well region and has the second type of conductivity, and the source region is formed in the second well region.

17. A method for fabricating a high voltage semiconductor transistor, comprising:
providing a lightly doped semiconductor substrate having a first type of conductivity;
forming a doped first well region in the substrate, the first well region having a second type of conductivity different from the first type of conductivity;
forming a first doped portion of a second well region in the first well region, the first portion occupying a region starting from the top surface of the first well region and extending down in the first well region;
forming a second doped portion of the second well region in the first well region, the second portion extending laterally from the first portion toward the drain, and both the first and second portions having the first type of conductivity;
forming an insulating layer on the substrate;
forming a gate structure on the substrate, the gate structure having a first part overlying the insulating layer, a second part overlying the first well region, and a third part overlying the first portion of the second well region; and
forming a source region in the first portion of the second well region and a drain region in the first well region, the source region and drain region residing on respective opposite sides of the gate structure.

18. The method of claim 17, wherein forming the source region and the drain region comprises forming the source region and drain region having the same type of conductivity.

19. The method of claim 17, wherein forming the source region comprises forming two oppositely doped regions in the first portion of the second well region.

20. The method of claim 17, wherein the lightly doped substrate is p-doped, the first well region is n-doped, and the second well region is p-doped.
